(19) United States
(12) Patent Application Publication
(10) Pub. No.: US 2025/0280699 A1
(43) Pub. Date: Sep. 4, 2025

(54) DISPLAY APPARATUS

(71) Applicant: LG Display Co., Ltd., Seoul (KR)

(72) Inventors: ChangYoon YANG, Seoul (KR); Meenwoo KIM, Paju-si (KR)

(73) Assignee: LG Display Co., Ltd., Seoul (KR)

(21) Appl. No.: 19/058,575

(22) Filed: Feb. 20, 2025

(30) Foreign Application Priority Data
Feb. 29, 2024 (KR) 10-2024-0030305

(51) Int. Cl. H10K 59/80; H10K 59/124

(52) U.S. Cl. CPC H10K 59/80515; H10K 59/124

(57) ABSTRACT

Provided is a display apparatus. The display apparatus includes a substrate including a plurality of sub-pixels; a thin film transistor on the substrate; a planarization layer on the thin film transistor; an anode disposed on the planarization layer and disposed for each sub-pixel; an emission layer disposed on the anode; and a cathode on the emission layer. The planarization layer includes a contact hole for connecting the anode and the thin film transistor and a groove portion located opposite the contact hole based on the anode.

### CROSS-REFERENCE TO RELATED APPLICATIONS

This application claims the priority of Korean Patent Application No. 10-2024-0030305 filed on Feb. 29, 2024, in the Korean Intellectual Property Office, the disclosure of which is incorporated herein by reference.

### BACKGROUND

### Technical Field

The present disclosure relates to a display apparatus, and more particularly, to a display apparatus which can improve a luminance viewing angle.

### Description of the Related Art

The field of display apparatuses which visually express electrical information signals is rapidly advancing. Thus, various studies on display apparatuses are ongoing to improve the performance, such as thin profile, lightness, and low power consumption.

Typical display apparatuses include a liquid crystal display (LCD) apparatus, a field emission display (FED) apparatus, an electro-wetting display (EWD) apparatus, an organic light emitting display (OLED) apparatus, and the like.

Electroluminescent display apparatuses including OLEDs are self-luminous display apparatuses and do not require a separate light source unlike LCDs. Thus, the electroluminescent display apparatuses can be manufactured lightly and thinly. Further, the electroluminescent display apparatuses are not only advantageous in terms of power consumption by low voltage driving, but also has excellent color implementation, response speed, viewing angle, and contrast ratio (CR). Therefore, the electroluminescent display apparatuses are expected to be utilized in various fields.

### BRIEF SUMMARY

The present disclosure provides a display apparatus which, among others, can suppress degradation of luminous efficacy and viewing angle of a light emitting diode.

The present disclosure provides a display apparatus which, among others, can suppress an asymmetric color shift (ASCS) occurring when varying an azimuth angle at the same viewing angle.

The present disclosure provides a display apparatus which, among others, can suppress a luminance occurring at a low viewing angle.

Technical features of the present disclosure are not limited to those above-mentioned, and other technical features, which are not mentioned above, can be clearly understood by those skilled in the art from the following descriptions.

A display apparatus according to an example embodiment of the present disclosure includes: a substrate including a plurality of sub-pixels; a thin film transistor on the substrate; a planarization layer on the thin film transistor; an anode disposed on the planarization layer and disposed for each sub-pixel; an emission layer disposed on the anode; and a cathode on the emission layer. The planarization layer includes a contact hole for connecting the anode and the thin film transistor and a groove portion located opposite the contact hole based on the anode.

Other detailed matters of the example embodiments are included in the detailed description and the drawings.

According to the present disclosure, a display apparatus includes an anode having a symmetrical shape on a cross section. Thus, it is possible to suppress an ASCS depending on an azimuth angle.

According to the present disclosure, the display apparatus includes a groove portion symmetrical to a contact hole in a planarization layer. Thus, it is possible to adjust the shape of the anode.

According to the present disclosure, the display apparatus can improve luminous efficacy and viewing angle.

According to the present disclosure, the display apparatus can improve the lifespan of a light emitting diode.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display apparatus according to an example embodiment of the present disclosure;

FIG. 2 is an enlarged plan view of an area PX of FIG. 1;

FIG. 3 is a cross-sectional view taken along a line I-I′ of FIG. 2;

FIG. 4 is a schematic cross-sectional view of an illustrative example of a display apparatus;

FIG. 5A and FIG. 5B are diagrams showing a spherical coordinate system on a display apparatus;

FIG. 6 is a plan view of a display apparatus according to another example embodiment of the present disclosure;

FIG. 7 is a cross-sectional view taken along a line II-II′ of FIG. 6;

FIG. 8 is a cross-sectional view of a display apparatus according to yet another example embodiment of the present disclosure;

FIG. 9 is a plan view of the display apparatus according to yet another example embodiment of the present disclosure;

FIG. 10 shows schematic cross-sectional views of light emitting diodes of display apparatuses according to Illustrative example 1 and Illustrative example 2, respectively; and

FIG. 11 is a graph showing an ASCS depending on a viewing angle and an azimuth angle measured from each of Illustrative example 1, Illustrative example 2, and an embodiment of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, the element or layer may be directly on another element or layer, or other element or lay may be interposed therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display apparatus according to example embodiments of the present disclosure will be described in detail with reference to accompanying drawings.

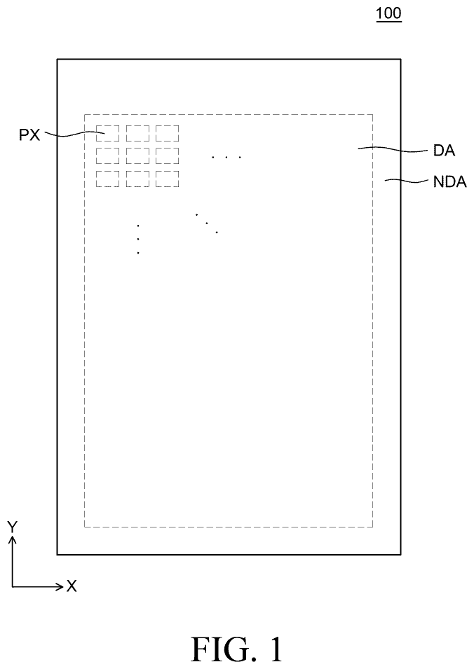

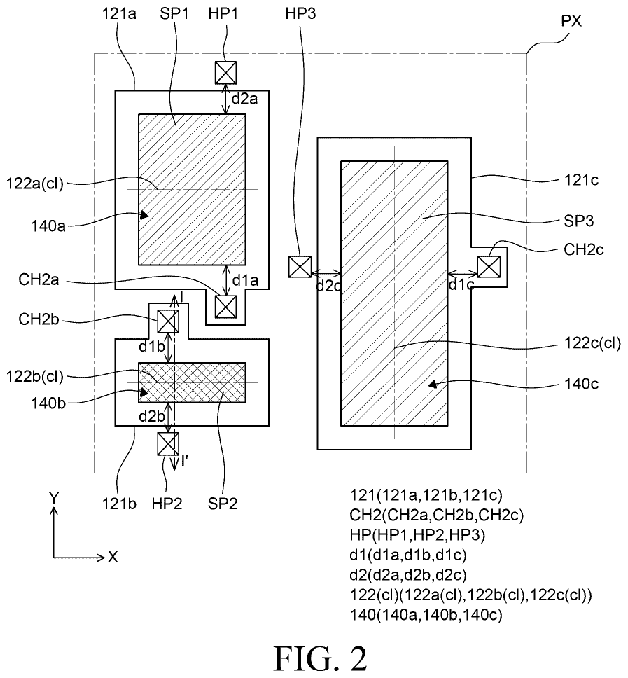

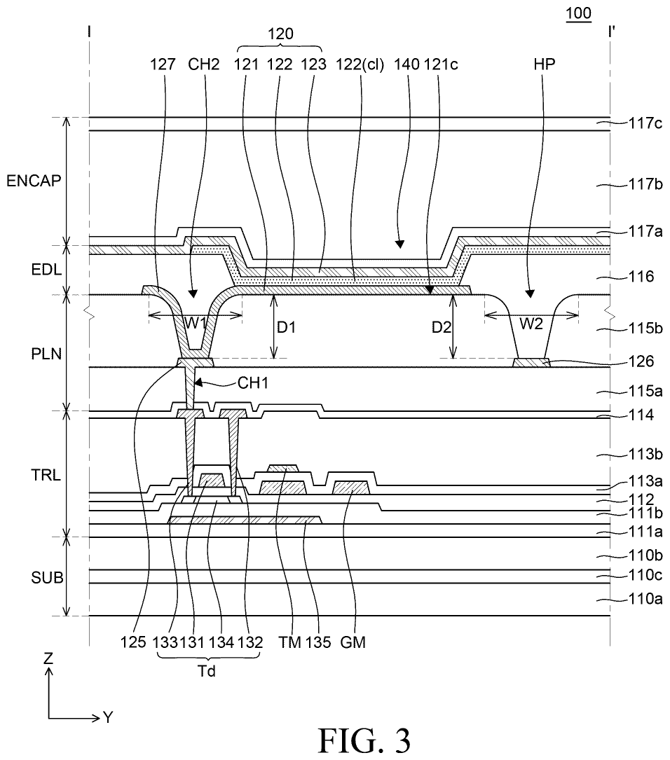

FIG. 1 through FIG. 3 are diagrams for explaining a display apparatus according to an example embodiment of the present disclosure. FIG. 1 is a plan view of the display apparatus according to an example embodiment of the present disclosure. FIG. 2 is an enlarged plan view of an area PX of FIG. 1. FIG. 3 is a cross-sectional view taken along a line I-I′ of FIG. 2.

Referring to FIG. 1, a display apparatus 100 includes a display area DA and a non-display area NDA. The display area DA is an area in which a plurality of pixels PX is disposed to substantially display images. The pixels PX including an emission area for displaying images and driving circuits for driving the pixels PX may be disposed in the display area DA. The non-display area NDA encloses the display area DA. The non-display area NDA is an area in which an image is not substantially displayed. Also, various lines, driver ICs, printed circuit boards, etc., for driving the pixels PX and the driving circuits disposed in the display area DA are disposed in the non-display area NDA.

Referring to FIG. 1, the plurality of pixels PX is disposed in the display area DA. The plurality of pixels PX is disposed in a matrix form. Referring to FIG. 2, each of the plurality of pixels PX includes a plurality of sub-pixels SP1, SP2 and SP3. Each of the sub-pixels SP1, SP2 and SP3 is an element for displaying one color and includes an emission area from which light is emitted and a non-emission area from which light is not emitted. In the present disclosure, an area where an emission layer is disposed is referred to as the emission area, and the other area is referred to as the non-emission area.

FIG. 2 illustrates anodes 121a, 121b and 121c, second contact holes CH2a, CH2b and CH2c, groove portions HP1, HP2 and HP3 constituting first to third sub-pixels SP1, SP2 and SP3 of the display apparatus 100.

One pixel PX may include a first sub-pixel SP1, a second sub-pixel SP2, and a third sub-pixel SP3. For example, referring to FIG. 2, the first sub-pixel SP1 and the second sub-pixel SP2 may be disposed with respect to one another in a second direction (e.g., a Y-axis direction), and the third sub-pixel SP3 may be disposed, with respect to one or more of the first sub-pixel SP1 or the second sub-pixel SP2, in a first direction (e.g., a X-axis direction) different from the second direction. However, the present disclosure is not limited thereto.

The first sub-pixel SP1, the second sub-pixel SP2, and the third sub-pixel SP3 may display colors different from one another. If necessary, some sub-pixels SP1, SP2 and SP3 may display the same color. Each of the first sub-pixel SP1, the second sub-pixel SP2, and the third sub-pixel SP3 may be one of a red sub-pixel, a green sub-pixel, a blue sub-pixel, or a white sub-pixel. In the present disclosure, it is described that the first sub-pixel SP1 is a green sub-pixel, the second sub-pixel SP2 is a red sub-pixel, and the third sub-pixel SP3 is a blue sub-pixel. However, the present disclosure is not limited thereto.

Referring to FIG. 1 through FIG. 3, the display apparatus 100 according to an example embodiment of the present disclosure includes a substrate SUB, a transistor layer TRL, a planarization layer PLN, a light emitting diode layer EDL, and an encapsulation layer ENCAP.

The substrate SUB serves to support various components included in the display apparatus 100 and may be made of an insulating material. The substrate SUB may include a first substrate 110a, a second substrate 110b, and an interlayer insulating film 110c. For example, the first substrate 110a and the second substrate 110b may be polyimide (PI) substrates. The interlayer insulating film 110c may be disposed between the first substrate 110a and the second substrate 110b. Since the substrate SUB is composed of the first substrate 110a, the second substrate 110b, and the interlayer insulating film 110c as described above, it is possible to suppress moisture permeation.

Various patterns 131, 132, 133 and 134 for forming transistors, such as a driving transistor Td, various insulating films 111a, 111b, 112, 113a, 113b and 114, and various metal patterns TM, GM and 135 may be disposed in the transistor layer TRL.

Hereinafter, a laminated structure of the transistor layer TRL will be described in more detail.

A multi-buffer layer 111a may be disposed on the second substrate 110b. A metal layer 135 may be disposed on the multi-buffer layer 111a. herein, the metal layer 135 may serve as a light shield and may also be referred to as a light shielding layer.

An active buffer layer 111b may be disposed on the multi-buffer layer 111a and the metal layer 135. An active layer 134 of the driving transistor Td may be disposed on the active buffer layer 111b. For example, the active layer 134 may be made of polysilicon (p-Si), amorphous silicon (a-Si), or an oxide semiconductor, but is not limited thereto.

A gate insulating film 112 may be disposed on the active layer 134. The gate insulating film 112 may be configured by a single layer or a multi-layer of silicon oxide (SiOx) and silicon nitride (SiNx).

A gate electrode 131 of the driving transistor Td may be disposed on the gate insulating film 112. The gate electrode 131 is disposed on the gate insulating film 112 so as to overlap the active layer 134. The gate electrode 131 may be made of various conductive materials, such as magnesium (Mg), aluminum (Al), nickel (Ni), chromium (Cr), molybdenum (Mo), tungsten (W), gold (Au) or an alloy thereof. However, the present disclosure is not limited thereto.

A gate material layer GM may be disposed on the gate insulating layer 112 at a location different from the location where the driving transistor Td is disposed.

A first interlayer insulating film 113a may be disposed on the gate electrode 131 and the gate material layer GM. A metal pattern TM may be disposed on the first interlayer insulating film 113a. A second interlayer insulating film 113b may be disposed on the first interlayer insulating film 113a so as to cover the metal pattern TM.

A source electrode 132 and a drain electrode 133 of the driving transistor Td may be disposed on the second interlayer insulating film 113b.

The source electrode 132 and the drain electrode 133 may be respectively connected to one side and the other side of the active layer 134 through contact holes provided in the second interlayer insulating film 113b, the first interlayer insulating film 113a, and the gate insulating film 112. The source electrode 132 and the drain electrode 133 may be made of various conductive materials, such as magnesium (Mg), aluminum (Al), nickel (Ni), chromium (Cr), molybdenum (Mo), tungsten (W), gold (Au) or an alloy thereof. However, the present disclosure is not limited thereto.

A part of the active layer 134 overlapping the gate electrode 131 may serve as a channel region. One of the source electrode 132 and the drain electrode 133 is connected to one side of the channel region in the active layer 134, and the other of the source electrode 132 and the drain electrode 133 is connected to the other side of the channel region in the active layer 134.

A passivation layer 114 may be disposed on the source electrode 132 and the drain electrode 133. The passivation layer 114 serves to protect the driving transistor Td, and may be configured by an inorganic film, such as a single layer or a multi-layer of silicon oxide (SiOx) and silicon nitride (SiNx).

The planarization layer PLN may be located on the transistor layer TRL. The planarization layer PLN may include a first planarization layer 115a and a second planarization layer 115b. The planarization layer PLN serves to protect the driving transistor Td and planarize an upper portion of the driving transistor Td. The first planarization layer 115a may be disposed on the passivation layer 114, and a first connection electrode 125 and a second connection electrode 126 may be disposed on the first planarization layer 115a.

The first connection electrode 125 may be connected to one of the source electrode 132 or the drain electrode 133 through a first contact hole CHI provided in the first planarization layer 115a. The second connection electrode 126 may be exposed through a groove portion HP provided in the second planarization layer 115b. The groove portion HP may be formed as a hole in the second planarization layer 115b.

The second planarization layer 115b may be disposed on the first connection electrode 125 and/or the first planarization layer 115a.

The second planarization layer 115b includes a second contact hole CH2 and the groove portion HP. The second contact hole CH2 serves to connect an anode 121 of a light emitting diode 120 to be described later with the first connection electrode 125. For example, a connection portion 127 is formed in the second contact hole CH2, which connects the anode 121 to the first connection electrode 125. In some implementations, the connection portion 127 is deposited as a same layer as the anode 121 and is integral to the anode 121, which extends within the second contact hole CH2. In some implementations, the connection portion 127 is a different material or a different layer from the anode 121. The groove portion HP is an area where a part of the second planarization layer 115b is removed. In some implementations, the anode 121 does not extend into the groove portion HP and is separated from the groove portion HP by a bank 116. Details of the second contact hole CH2 and the groove portion HP will be described below. Due to the groove portion HP, the anode 121 described below has a symmetrical shape.

The light emitting diode layer EDL may be located on the second planarization layer 115b.

Hereinafter, a laminated structure of the light emitting diode layer EDL will be described in detail.

The light emitting diode 120 including the anode 121, an emission layer 122, and a cathode 123 may be provided on the second planarization layer 115b.

The anode 121 may be disposed on the second planarization layer 115b. Herein, the anode 121 may be electrically connected to the first connection electrode 125 through the second contact hole CH2 provided in the second planarization layer 115b. The anode 121 may be made of a metallic material.

The display apparatus 100 may be a top emission display apparatus in which light emitted from the light emitting diode 120 is emitted to above the substrate SUB on which the light emitting diode 120 is disposed. In this case, the anode 121 may further include a transparent conductive layer, and a reflective layer on the transparent conductive layer. The transparent conductive layer may be made of a transparent conductive material, such as ITO and IZO. The reflective layer may be made of, for example, silver (Ag), aluminum (Al), gold (Au), molybdenum (Mo), tungsten (W), chromium (Cr) or an alloy thereof. The anode 121 may be separately formed for each of the first sub-pixel SP1, the second sub-pixel SP2, and the third sub-pixel SP3.

The bank 116 is disposed on the anode 121 and the second planarization layer 115b. The bank 116 may cover an edge of the anode 121 and border an emission area 140. Herein, a portion of the bank 116 corresponding to an emission area of a sub-pixel may be opened. A portion 121C of the anode 121 may be exposed through the opened portion of the bank 116. The bank 116 may be made of an inorganic insulating material, such as silicon nitride (SiNx) or silicon oxide (SiOx), or an organic insulating material, such as benzocyclobutene resin, acrylic resin or imide resin, but is not limited thereto.

The emission layer 122 may be disposed on and around the opened portion of the bank 116. That is, the emission layer 122 may be disposed on the anode 121 exposed through the opened portion of the bank 116. The emission layer 122 may include a plurality of organic films. The emission layer 122 is a layer in which electrons and holes are recombined to emit light. Thus, the emission layers 122 which emit light of corresponding colors may be disposed in the sub-pixels SP1, SP2 and SP3, respectively. For example, a green organic emission layer may be disposed in the first sub-pixel SP1, a red organic emission layer may be disposed in the second sub-pixel SP2, and a blue organic emission layer may be disposed in the third sub-pixel SP3. However, the present disclosure is not limited thereto. A layer of the emission layer 122 may be disposed to extend beyond the emission area 140, although the portion of the emission layer 122 within the emission area is referred to as an emission layer of the relevant sub-pixel when a dimension or a side of the emission layer 122 is discussed. Similarly, a layer of the anode 121 may be disposed to extend beyond the emission area 140, e.g., including portions not exposed by the opened portion of the bank 116. The portion of the anode 121 within the emission area of a sub-pixel is referred to as an anode of the relevant sub-pixel when a dimension or a side of the anode 121 is discussed. The groove HP may be filled, in particular fully or partially, by the bank 116.

The cathode 123 may be disposed on the emission layer 122. The cathode 123 is not patterned for each of the sub-pixels SP1, SP2 and SP3, but may be provided as a layer covering the emission layer 122 and the bank 116. That is, the cathode 123 may be provided as a single layer in the first sub-pixel SP1, the second sub-pixel SP2, and the third sub-pixel SP3. The cathode 123 may be made of a metal material having a low work function to smoothly supply electrons to the emission layer 122. For example, the cathode 123 may be made of a metal material selected from calcium (Ca), barium (Ba), aluminum (Al), silver (Ag), and alloys including one or more of them, but is not limited thereto. When the display apparatus 100 is driven as a top emission type, the cathode 123 is formed to have a very small thickness to be substantially transparent.

In order to improve luminous efficiency of the light emitting diode 120, the light emitting diode 120 may further include a hole injection layer, a hole transport layer, an electron transport layer, an electron injection layer (not shown for brevity), etc. For example, the hole injection layer and the hole transport layer may be disposed between the anode 121 and the emission layer 122. Also, the electron transport layer and the electron injection layer may be disposed between the emission layer 122 and the cathode 123. Further, a hole blocking layer or an electron blocking layer may be disposed to further improve a recombination efficiency of the holes and electrons in the emission layer 122.

The encapsulation layer ENCAP may be located on the light emitting diode layer EDL.

The encapsulation layer ENCAP may have a monolayer structure or a multilayer structure. For example, the encapsulation layer ENCAP may include a first encapsulation layer 117a, a second encapsulation layer 117b, and a third encapsulation layer 117c.

Herein, the first encapsulation layer 117a and the third encapsulation layer 117c may be inorganic films, and the second encapsulation layer 117b may be an organic film. Among the first encapsulation layer 117a, the second encapsulation layer 117b, and the third encapsulation layer 117c, the second encapsulation layer 117b may be the thickest and may serve as a planarization layer.

The first encapsulation layer 117a may be disposed on the cathode 123 and most adjacent to the light emitting diode 120. The first encapsulation layer 117a may be made of an inorganic insulating material suitable for low temperature deposition. For example, the first encapsulation layer 117a may be made of silicon nitride (SiNx), silicon oxide (SiOx), silicon oxynitride (SiON) or aluminum oxide (Al₂O₃). The first encapsulation layer 117a is deposited in a low temperature atmosphere. Thus, the first encapsulation layer 117a can suppress damage to the emission layer 122 containing an organic material vulnerable to a high temperature atmosphere during a deposition process.

The second encapsulation layer 117b may be provided to have a smaller area size than the first encapsulation layer 117a. For example, the second encapsulation layer 117b may be provided to expose ends of the first encapsulation layer 117a. For example, the first encapsulation layer 117a extends laterally beyond the second encapsulation layer 117b. The second encapsulation layer 117b may serve as a buffer to reduce stress between layers caused by bending of a flexible display apparatus and may also serve to enhance planarization performance.

For example, the second encapsulation layer 117b may be made of an organic insulating material, such as acrylic resin, epoxy resin, polyimide, polyethylene, or silicon oxycarbide (SiOC). For example, the second encapsulation layer 117b may be prepared by an inkjet method but is not limited thereto.

The third encapsulation layer 117c may be provided on the substrate SUB including the second encapsulation layer 117b so as to cover an upper surface and a side surface of each of the second encapsulation layer 117b and the first encapsulation layer 117a. The third encapsulation layer 117c may reduce or block the permeation of external moisture or oxygen into the first encapsulation layer 117a or the second encapsulation layer 117b. For example, the third encapsulation layer 117c may be made of an inorganic insulating material, such as silicon nitride (SiNx), silicon oxide (SiOx), silicon oxynitride (SiON) or aluminum oxide (Al₂O₃).

Although not illustrated in FIG. 3, a color filter may be disposed on the encapsulation layer ENCAP. However, the present disclosure is not limited thereto.

Although not illustrated in FIG. 3, a touch sensing layer may be further disposed on the encapsulation layer ENCAP. However, the present disclosure is not limited thereto.

Although not illustrated in FIG. 3, a polarization layer may be further disposed on the encapsulation layer ENCAP. The polarization layer disposed in the display area DA of the substrate SUB serves to suppress reflection of external light. When the display apparatus 100 is used outdoors, external natural light enters to be reflected by the reflective layer included in the anode 121 of the light emitting diode 120 or reflected by a metal electrode disposed under the light emitting diode 120. In this case, images of the display apparatus 100 may not be visibly recognized due to the reflected light. The polarization layer polarizes the light entering from the outside toward a specific direction and suppresses emission of the reflected light to the outside of the display apparatus 100.

Although not illustrated in FIG. 3, a cover glass may be bonded onto the polarization layer by means of an adhesive layer. The adhesive layer may serve to bond the components of the display apparatus 100 to each other. The adhesive layer may be made of an optically transparent display adhesive, such as pressure-sensitive adhesive, optical clear adhesive (OCA) or optical clear resin (OCR) but is not limited thereto. The cover glass may serve to protect the components of the display apparatus 100 from external impacts and suppress damage such as scratches.

The groove portion HP provided in the second planarization layer 115b of the display apparatus 100 according to an example embodiment of the present disclosure will be described in detail with reference to FIG. 2 and FIG. 3.

The display apparatuses 100 have a limitation in thickness for thin profile and lightness, and a part of an upper surface of the planarization layer may not be fully flat due to various reasons. For example, a contact hole for connecting an anode disposed on the planarization layer to a thin film transistor is formed in the planarization layer. In this case, the planarization layer around the contact hole may be lost or lowered in height during a process of forming the contact hole. Thus, when the anode is deposited on the planarization layer after the contact hole is formed, the anode is formed along the shape of the upper surface of the planarization layer. Therefore, the anode around the contact hole may be partially inclined along the upper surface of the planarization layer. In general, the contact hole is disposed to overlap a side portion of the anode. Thus, the side portion of the anode overlapping the contact hole has a different inclination from the other side portion of the anode. Therefore, the anode may be disposed on the planarization layer so as to have an asymmetrical shape on a cross section. This structure will be described together with a structure of a display apparatus according to illustrative examples.

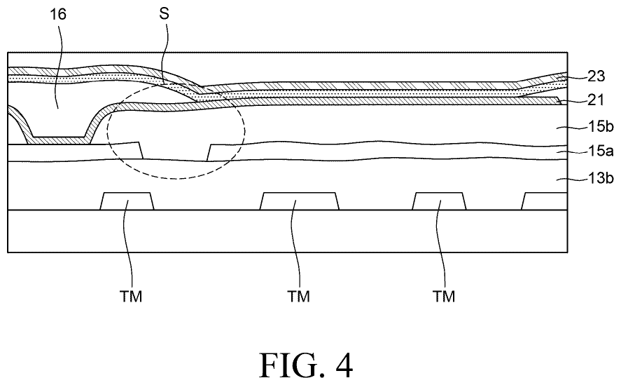

FIG. 4 is a schematic cross-sectional view of an illustrative example. Referring to FIG. 4, in the display apparatus according to the illustrative example, upper surfaces of an insulating film 13b and planarization layers 15a and 15b located at an upper portion are not even due to a plurality of metal patterns TM located at a lower portion. Therefore, a surface of an anode 21 adjacent to a contact hole is not flat, but has an uneven shape S. Also, it can be seen that a side portion of the anode 21 overlapping the contact hole is further inclined downwards than the other side portion of the anode 21, and the anode 21 is laterally asymmetrical. According to Illustrative example shown in FIG. 4, it can be seen that a left side portion and a right side portion of the anode 21 are different in inclination by about 2.0°.

As described above, if an anode has an asymmetrical shape with a different inclination between one side portion and the other side portion of the anode, luminous efficacy of a sub-pixel may be degraded. For example, if the anode is asymmetrically disposed, a light emitting diode may also have an asymmetrical and uneven surface, which may result in degradation of viewing angle. For example, when color coordinates are measured while varying an azimuth angle at the same viewing angle, an ASCS may occur.

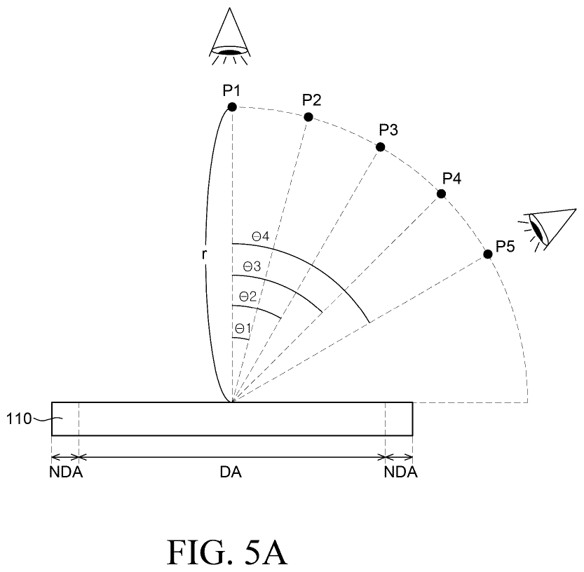

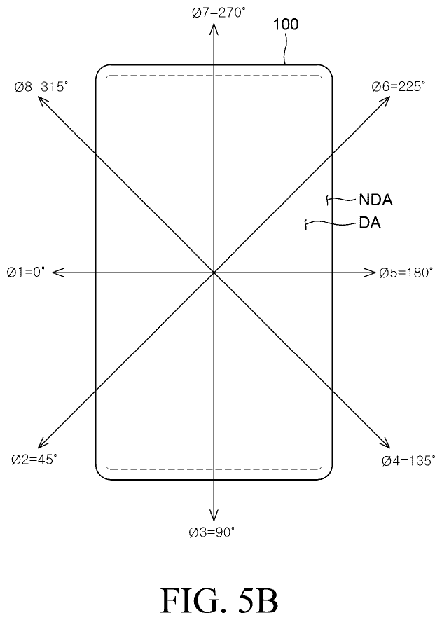

Hereinafter, an ASCS, which occurs when varying an azimuth angle at the same viewing angle, will be described with reference to FIG. 5A and FIG. 5B.

FIG. 5A and FIG. 5B are diagrams showing a spherical coordinate system on the display apparatus.

As shown in FIG. 5A and FIG. 5B, the spherical coordinate system may be referred to on the display apparatus 100. The origin of the spherical coordinate system may be located at the center of the display area DA of the display apparatus 100. The spherical coordinate system is used to distinguish measurement points for measuring the display quality of the display apparatus 100.

The coordinates of the spherical coordinate system may be denoted by r, θ and Φ. Herein, r is the distance from the origin to a measurement point, θ is the angle between a Z-axis (or a normal axis of the display apparatus 100) and a straight line along the original and the measurement point, and Φ is the angle between a Y-axis (or a horizontal axis passing through the center of the display apparatus 100) and a straight line in which the straight line along the origin and the measurement point is projected in an XY plane (or a front surface of the display apparatus 100). For the convenience of description, θ is referred to as a viewing angle and Φ is referred to as an azimuth angle.

FIG. 5A illustrates five measurement points P1 to P5. A first viewing angle of a first measurement point P1 is 0°. Each of second to fifth viewing angles θ1, θ2, θ3 and θ4 of second to fifth measurement points P2 to P5 has a certain angle from the Z-axis (or the normal axis of the display apparatus 100). The second to fifth viewing angles θ1, θ2, θ3 and θ4 of second to fifth measurement points P2 to P5 may be 15°, 30°, 45° and 60°, respectively. The second to fifth viewing angles θ1, θ2, θ3 and θ4 of second to fifth measurement points P2 to P5 may be 20°, 40°, 60° and 80°, respectively. The second to fifth viewing angles θ1, θ2, θ3 and θ4 of second to fifth measurement points P2 to P5 may also be 10°, 20°, 30° and 40°, respectively.

FIG. 5B illustrates eight azimuth angles Φ1 to Φ8 as an example. First to eighth azimuth angles may be 0°, 45°, 90°, 135°, 180°, 225°, 270° and 315°, respectively.

The ASCS occurring when varying an azimuth angle at the same viewing angle may be measured as variations Δu′ and Δv′ in the color coordinates while varying azimuth angles Φ1 to Φ8 at a certain viewing angle θ1, θ2, θ3 or θ4 in a Z-axis direction. The variations Δu′ and Δv′ in the color coordinates may be based on color coordinates u′ and v′ of the CIE 1976 color coordinate system.

The display apparatus 100 according to an example embodiment of the present disclosure includes the groove portion HP corresponding to the second contact hole CH2 provided in the second planarization layer 115b. The groove portion HP may be disposed corresponding to each sub-pixel. For example, the groove portion HP may be disposed in each of the first sub-pixel SP1, the second sub-pixel SP2, and the third sub-pixel SP3. For example, a first groove portion HP1 may be disposed in the first sub-pixel SP1, a second groove portion HP2 may be disposed in the second sub-pixel SP2, and a third groove portion HP3 may be disposed in the third sub-pixel SP3. The first groove portion HP1, the second groove portion HP2, and the third groove portion HP3 may be different from one another in shape, size, depth, position, etc. The shapes of the first groove portion HP1, the second groove portion HP2, and the third groove portion HP3 may vary depending on the shapes of second contact holes CH2a, CH2b and CH2c disposed in the respective sub-pixels.

For example, the groove portion HP may be located opposite the second contact hole CH2 based on or with respect to the anode 121 and/or across a center line 122(cl) of the emission area 140 (122a(cl), 122b(cl), 122c(cl) shown in FIG. 2) between the groove portion HP and the corresponding second contact hole CH2. For example, referring to FIG. 2, the groove portion HP1 of the first sub-pixel SP1 is located opposite the second contact hole CH2a provided in the second planarization layer 115b of the first sub-pixel SP1 in the Y-axis direction across center line 122a(cl) of the emission area 140a. For example, the groove portion HP1 is substantially symmetrical in position to the second contact hole CH2a in position with respect to the center line 122a(cl) along an X-axis. FIG. 2 illustrates that the groove portion HP1 is symmetrical in position to the second contact hole CH2a based on the center line 122a(cl) along the X-axis. However, the present disclosure is not limited thereto. A center line of an emission area can be any line that passes through a center of the emission area and the groove portion HP may be symmetrical in position to the second contact hole CH2 based on any of such center lines that pass through a center of the emission area 140. Alternatively or additionally, the groove portion HP may be symmetrical to the second contact hole CH2 based on a center line that passes through a center of the respective anode 121 or a center of the respective emission layer 122. For example, the groove portion HP2 of the second sub-pixel SP2 may be located opposite the second contact hole CH2b of the second sub-pixel SP2 in the Y-axis direction, e.g., symmetrical based on center line 122b(cl). Further, the groove portion HP3 of the third sub-pixel SP3 may be located opposite the second contact hole CH2c of the third sub-pixel SP3 in the X-axis direction, e.g., symmetrical based on center line 122c(cl). The center line of the emission area may correspond to a center line of the respective anode. The emission area may have a symmetrical planar shape, and the center line may correspond to a symmetry axis of the emission area.

FIG. 2 illustrates that all the first sub-pixel SP1, the second sub-pixel SP2, and the third sub-pixel SP3 include the groove portions HP (HP1, HP2 and HP3). However, the present disclosure is not limited thereto. For example, in some implementations, some but not all sub-pixels include the groove portions HP. For example, in some implementations, only the second sub-pixel SP2, which is a red sub-pixel, include the second groove portion HP2. In this case, the first sub-pixel SP1, which is a green sub-pixel, and the third sub-pixel SP3, which is a blue sub-pixel, may not include the first groove portion HP1 and the third groove portion HP3, respectively. Referring to FIG. 2, the second contact hole CH2b of the second sub-pixel SP2 may be provided in a narrow space between the first sub-pixel SP1 and the second sub-pixel SP2. In this case, it is difficult to provide an additional component for planarizing the second planarization layer 115b and the anode 121. Thus, in the second sub-pixel SP2, the groove portion HP2 may be disposed in a wide space opposite the second contact hole CH2.

Referring to FIG. 3, the groove portion HP is located opposite the second contact hole CH2 in, e.g., the Y-axis direction. The groove portion HP may have substantially the same width W2 and the same depth D2 as those (W1, D1) of the second contact hole CH2. Since the groove portion HP is provided opposite the second contact hole CH2, an upper surface of the second planarization layer 115b adjacent to the second contact hole CH2 and the groove portion HP is lowered in height at the same inclination. That is, both portions of the second planarization layer 115b adjacent to the second contact hole CH2 and the groove portion HP are substantially symmetrical to each other in the shape or profile. Also, the anode 121 and the emission layer 122 is disposed on the second planarization layer 115b. Thus, a side portion of the anode 121 or the emission layer 122 adjacent to the second contact hole CH2 and the other side portion of the anode 121 or emission layer 122 adjacent to the groove portion HP are lowered in height at the same inclination along the upper surface of the second planarization layer 115b. That is, the side portion of the anode 121 or emission layer 122 adjacent to the second contact hole CH2 and the other side portion of the anode 121 or emission layer 122 adjacent to the groove portion HP are symmetrical to each other based on the Y-axis direction.

In this case, an ASCS occurring when varying an azimuth angle at the same viewing angle in the Z-axis direction may be remarkably decreased. For example, in the second sub-pixel SP2, the second contact hole CH2 and the groove portion HP are symmetrical to each other based on the anode 121 in the Y-axis direction. Thus, an ASCS of the second sub-pixel SP2 measured at an azimuth angle of 90° and an azimuth angle of 270° at the same viewing angle in the Z-axis direction may be decreased.

Meanwhile, the groove portion HP may have substantially the same shape as the second contact hole CH2. However, the present disclosure is not limited thereto. For example, the depth D2 of the groove portion HP may be 90% to 110% or 94% to 105% of the depth D1 of the second contact hole CH2. Also, the width W2 of the groove portion HP on a cross section may be 75% to 125% of the width W1 of the second contact hole CH2. When the depth and the size of the groove portion HP satisfy the above ranges based on the second contact hole CH2, referred to as similarity ranges or threshold ranges, a difference in inclination between the anode adjacent to the groove portion HP and the anode adjacent to the second contact hole CH2 may be decreased to less than 2° or 1°. Thus, an ASCS occurring when varying an azimuth angle at the same viewing angle in the Z-axis direction may be decreased.

A distance d2 (d2a, d2b, d2c shown on FIG. 2) from a side portion of the emission area 140 or the anode 121 in the emission area 140 to the groove portion HP may be in a similarity range of 80% to 120% of a distance d1 (d1a, d1b, d1c shown on FIG. 2) from the other side portion of the emission area 140 or the anode 121 in the emission area 140 to the second contact hole CH2. In other words, a difference between distance d2 and distance d1 is within a threshold range, e.g., 0% to 20% of d1. When the distance d2 from the side portion of the emission area 140 or the anode 121 to the groove portion HP satisfies the above range based on the second contact hole CH2, the flatness of the anode 121, and thus the emission layer 122, can be improved in consideration of a process margin. The distance d2 from the side portion of the emission area 140 or the anode 121 in the emission area 140 to the groove portion HP may vary depending on a sub-pixel array structure and the type of a sub-pixel. For example, referring to FIG. 2, the distance d2a from a side portion of the emission area 140a or the anode 121a of the first sub-pixel SP1, which is, e.g., a green sub-pixel, to the groove portion HP1 may be 86% to 114% of the distance d1a from the other side portion of the emission area 140a or the anode 121a to the second contact hole CH2a. Also, the distance d2b from a side portion of the emission area 140b or the anode 121b of the second sub-pixel SP2, which is a red sub-pixel, to the groove portion HP2 may be 86% to 114% of the distance d1b from the other side portion of the emission area 140b or the anode 121b to the second contact hole CH2b. Further, the distance d2c from a side portion of the emission area 140c or the anode 121c of the third sub-pixel SP3, which is a blue sub-pixel, to the groove portion HP3 may be 83% to 117% of the distance d1c from the other side portion of the emission area 140c or the anode 121c to the second contact hole CH2c. When the distance from a side portion of an emission area 140 (or the anode 121 in the emission area 140 to the groove portion HP satisfies the above ranges, a difference in inclination between the anode adjacent to the groove portion HP and the anode adjacent to the second contact hole CH2 may be decreased. Also, it is possible to suppress a decrease in inclination of the anode adjacent to the groove portion HP in consideration of the distance between the sub-pixels.

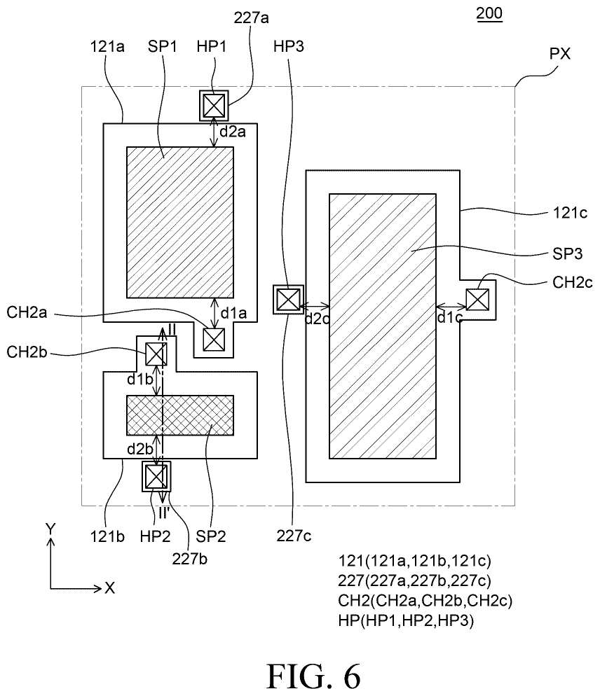

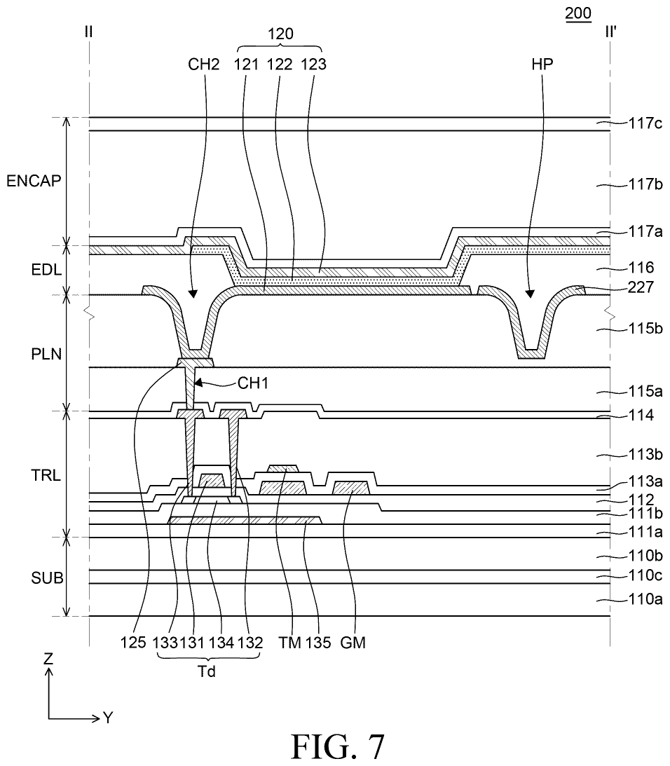

FIG. 6 is a plan view of a display apparatus according to an example embodiment of the present disclosure. FIG. 7 is a cross-sectional view taken along a line II-II′ of FIG. 6.

A display apparatus 200 shown in FIG. 6 and FIG. 7 is substantially the same as the display apparatus 100 shown in FIG. 2 and FIG. 3 except that the display apparatus 200 further includes a dummy electrode 227 but does not include a second connection electrode. Therefore, redundant description thereof will be omitted.

Referring to FIG. 6 and FIG. 7, the dummy electrode 227 is disposed in the groove portion HP formed in the second planarization layer 115b. The dummy electrode 227 may be made of the same material on the same layer as the anode 121. The dummy electrode 227 causes a portion of the anode 121 to sag along the shape of a corresponding portion of the anode 121 inclined by the second contact hole CH2. Thus, the anode 121 has a symmetrical shape. The dummy electrode 227 may not be connected to the anode 121.

For example, referring to FIGS. 6 and 7, the dummy electrode 227 is provided in the groove portion HP so as to be spaced apart from the anode 121 and thus has an island shape. The dummy electrode 227 as well as the groove portion HP corresponds to the second contact hole CH2 and the anode 121 disposed in the second contact hole CH2. Thus, when a side portion of the anode 121 is inclined by the second contact hole CH2, the other side portion of the anode 121 may also be inclined accordingly. Therefore, the side portion and the other side portion of the anode 121 may be symmetrical to each other. Herein, a second connection electrode is not disposed under the dummy electrode 227. However, the present disclosure is not limited thereto.

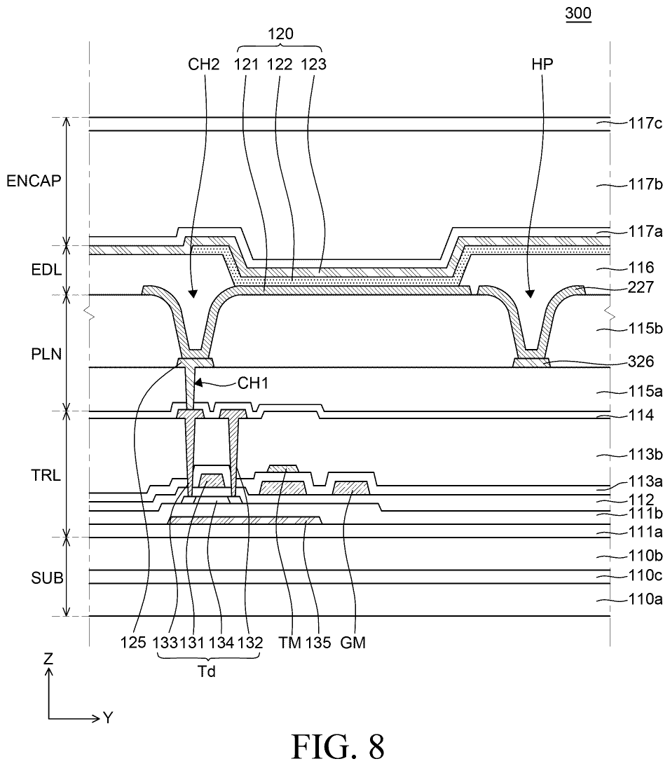

FIG. 8 is a cross-sectional view of a display apparatus according to an example embodiment of the present disclosure.

A display apparatus 300 shown in FIG. 8 is substantially the same as the display apparatus 200 shown in FIG. 6 and FIG. 7 except that the display apparatus 300 further includes a second connection electrode 326 and the dummy electrode 227 is in contact with the second connection electrode 326. Therefore, redundant description thereof will be omitted.

In the display apparatus 300 shown in FIG. 8, the second connection electrode 326 is disposed on the first planarization layer 115a so as to correspond to the groove portion HP. Since the groove portion HP exposes the second connection electrode 326, the dummy electrode 227 is in direct contact with the second connection electrode 326 through the groove portion HP. The second connection electrode 326 may be connected to a power line. In this case, a resistance can be reduced by the dummy electrode 227. Thus, a voltage drop (IR Drop) can be improved.

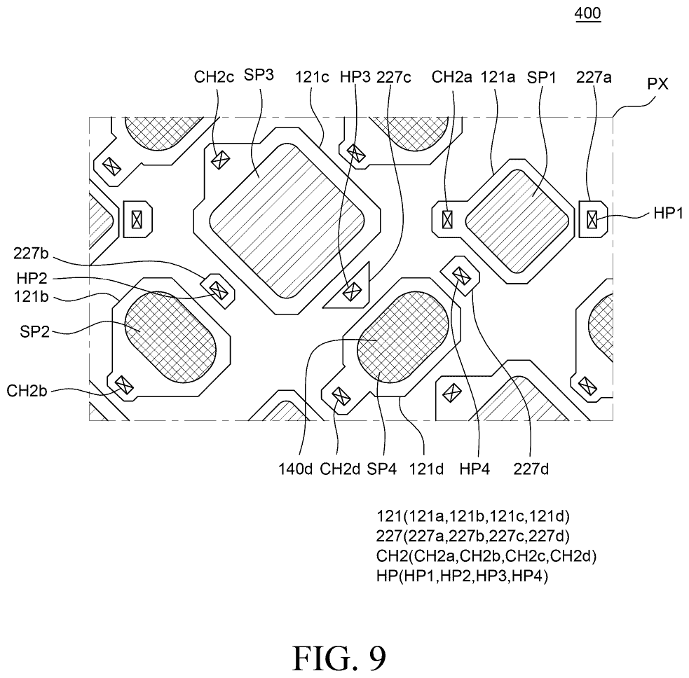

FIG. 9 is a plan view of the display apparatus according to an example embodiment of the present disclosure.

The display apparatus 400 shown in FIG. 9 is substantially the same as the display apparatus 100 shown in FIG. 2 except that the display apparatus 400 further includes a fourth sub-pixel, and the groove portion HP and the dummy electrode 227 in the fourth sub-pixel. Therefore, redundant description thereof will be omitted.

Referring to FIG. 9, one pixel PX may further include a fourth sub-pixel SP4. The fourth sub-pixel SP4 may display the same color as or a different color from one of the first sub-pixel SP1, the second sub-pixel SP2, and the third sub-pixel SP3. For example, the sub-pixels may be disposed to have a pentile structure in which the first sub-pixel SP1 and the third sub-pixel SP3 are a red sub-pixel and a blue sub-pixel, respectively, and both the second sub-pixel SP2 and the fourth sub-pixel SP4 are green sub-pixels.

In this case, each of the first sub-pixel SP1, the second sub-pixel SP2, the third sub-pixel SP3, and the fourth sub-pixel SP4 may include the groove portion HP and the dummy electrode 227. Herein, the groove portion HP and the dummy electrode 227 may be disposed opposite the second contact hole CH2 formed in the second planarization layer 115b. For example, referring to FIG. 9, the groove portion HP and the dummy electrode 227 in the first sub-pixel SP1 may be disposed at a position symmetrical to the second contact hole CH2 in the X-axis direction. Thus, the anode 121 may have a symmetrical inclination. Likewise, the groove portion HP and the dummy electrode 227 in each of the second sub-pixel SP2 and the fourth sub-pixel SP4 may be disposed at a position symmetrical to the second contact hole CH2 in a diagonal direction in the XY plane. Also, the groove portion HP and the dummy electrode 227 in the third sub-pixel SP3 may be disposed at a position symmetrical to the second contact hole CH2 in the diagonal direction in the XY plane.

In the present disclosure, the display apparatus 100 has been described as a top emission display apparatus. However, the present disclosure is not limited thereto. The display apparatus 100 may be implemented as a bottom emission display apparatus. In the bottom emission display apparatus 100, the anode 121 may be made of only a transparent conductive material without the reflective layer. However, even in the bottom emission display apparatus 100, the groove portion HP and the dummy electrode 227 may be provided on the planarization layer in order for the anode 121 whose side portion sags due to a contact hole to have a symmetrical structure.

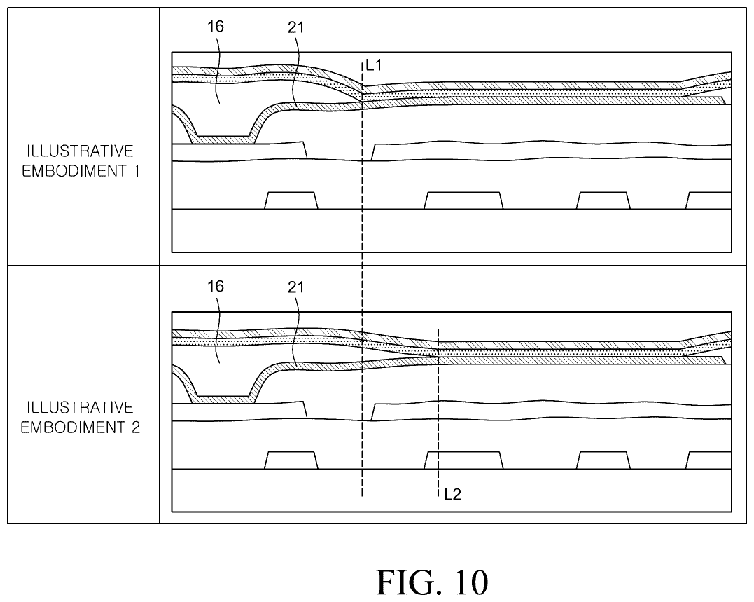

Hereinafter, effects of forming a groove portion will be described in more detail with reference to Embodiment of the present disclosure and Illustrative examples. However, the following Embodiments are for illustration of the present disclosure, and the scope of the present disclosure is not limited by the following Embodiments. The structures of Illustrative examples will be described with reference to FIG. 10. FIG. 10 shows schematic cross-sectional views of light emitting diodes of display apparatuses according to Illustrative example 1 and Illustrative example 2, respectively.

Referring to FIG. 10, Illustrative example 1 has a structure in which an anode is connected to a first connection electrode through a second contact hole, as a cross section of a red sub-pixel. Herein, the second contact hole is spaced apart by 1.4 μm from a side portion of the anode 21. Referring to FIG. 10, a side portion of the anode 21 sags due to the second contact hole. In Illustrative example 1, a difference in inclination between a side portion and the other side portion of the anode 21 adjacent to the second contact hole was 2.1°.

In comparison with Illustrative example 1, Illustrative example 2 has a structure in which a bank 16 extends toward an emission area, as a cross section of a red sub-pixel. That is, an end of the bank 16 of Illustrative example 1 is aligned with L1, whereas an end of the bank 16 of Illustrative example 2 is aligned with L2. Thus, the second contact hole is spaced apart by 2.4 μm from a side portion of the anode 21. In Illustrative example 2, the bank 16 extends toward the emission area. Therefore, a sagging portion of the anode 21 can be covered by the second contact hole, and, thus, the anode 21 in a portion opened by the bank 16 may have a flat shape. In Illustrative example 2, a difference in inclination between a side portion and the other side portion of the anode 21 adjacent to the second contact hole was 1.6°.

In an embodiment of the present disclosure, the groove portion HP was provided opposite the second contact hole CH2 of the red sub-pixel as shown in FIG. 2 and FIG. 3. Herein, the second contact hole CH2 is spaced apart by 1.4 μm from a side portion of the anode 121, and the groove portion HP is spaced apart by 1.4 μm from the other side portion of the anode 121.

Hereinafter, an ASCS occurring when varying an azimuth angle at the same viewing angle was measured from each of Illustrative example 1, Illustrative example 2, and Embodiment 1 of the present disclosure.

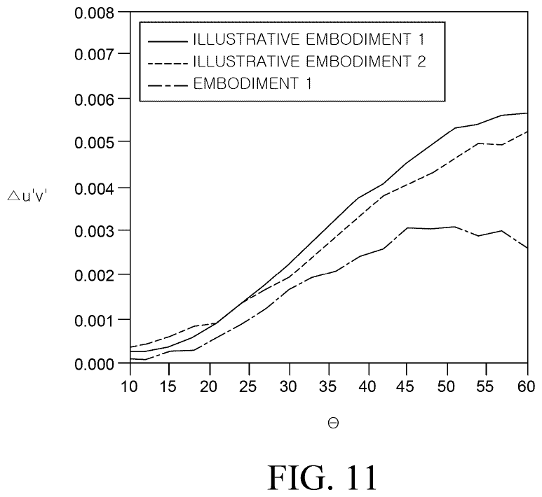

FIG. 11 is a graph showing an ASCS depending on a viewing angle and an azimuth angle measured from each of Illustrative example 1, Illustrative example 2, and Embodiment 1 of the present disclosure. FIG. 11 shows ASCS values (Δu′v′) between an azimuth angle Φ of 90° and an azimuth angle Φ of 270° as a viewing angle θ in the Z-axis varies.

Referring to FIG. 11, it can be seen that an ASCS is decreased in Illustrative example 2 compared to Illustrative example 1, but the effect thereof is insignificant. However, it can be seen that an ASCS is decreased by about 40% in Embodiment 1 of the present disclosure compared to Illustrative example 1. Also, in Illustrative example 2, the bank extends to cover a non-flat portion of the anode, and, thus, the emission area of the sub-pixel is decreased in size, which results in a decrease in lifespan of the light emitting diode. However, in Embodiment 1 of the present disclosure, a flat portion of the anode is increased in size and the anode has a symmetrical shape without a decrease in size of the emission area. Thus, the emission area can also be increased in size. Therefore, the lifespan can be improved in Embodiment 1 of the present disclosure compared to Illustrative example 2.

The example embodiments of the present disclosure can also be described as follows:
According to an aspect of the present disclosure, there is provided a display apparatus. The display apparatus includes a substrate including a plurality of sub-pixels; a thin film transistor on the substrate; a planarization layer on the thin film transistor; an anode disposed on the planarization layer and disposed for each sub-pixel; an emission layer disposed on the anode; and a cathode on the emission layer. The planarization layer includes a contact hole for connecting the anode and the thin film transistor and a groove portion located opposite the contact hole based on the anode.

The groove portion may be disposed to be symmetrical to the contact hole based on the anode.

The contact hole may be spaced apart by a predetermined distance from a side portion of the anode, and the groove portion may be spaced apart by the predetermined distance from the other side portion of the anode.

A distance from the other side portion of the anode to the groove portion may be 80% to 120% of a distance from the side portion of the anode to the contact hole.

The anode may be laterally symmetrical based on a cross section crossing the side portion and the other side portion of the anode.

The planarization layer may include a first planarization layer on the thin film transistor and a second planarization layer on the first planarization layer, the contact hole may include a first contact hole provided in the first planarization layer and a second contact hole provided in the second planarization layer, and the groove portion may have the same depth as the second contact hole.

The display apparatus may further comprise a first connection electrode and a second connection electrode on the first planarization layer. The second contact hole may expose the first connection electrode and connect the first connection electrode to the anode. The groove portion may overlap the second connection electrode and expose the second connection electrode.

The display apparatus may further comprise a dummy electrode disposed in the groove portion. The dummy electrode may be provided on the same layer as the anode.

The dummy electrode may be spaced apart by a predetermined distance from the anode.

The display apparatus may further comprise a first connection electrode and a second connection electrode on the first planarization layer. The anode may be in contact with the first connection electrode through the second contact hole, and the dummy electrode may be in contact with the second connection electrode through the groove portion.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a plurality of sub-pixels;
a thin film transistor on the substrate;
a planarization layer on the thin film transistor;
an anode disposed on the planarization layer and disposed for each sub-pixel;
an emission layer disposed on the anode; and
a cathode on the emission layer,
wherein the planarization layer includes a contact hole for connecting the anode and the thin film transistor and a groove portion located opposite to the contact hole based on the anode.

2. The display apparatus according to claim 1, wherein the groove portion is disposed to be substantially symmetrical to the contact hole based on the anode.

3. The display apparatus according to claim 2, wherein the contact hole is spaced apart by a first distance from a first side portion of the anode, the groove portion is spaced apart by a second distance from a second side portion of the anode, the second side portion opposite to the first side portion, and the second distance is within a threshold range of a percentage of the first distance.

4. The display apparatus according to claim 3, wherein the second distance from the second side portion of the anode to the groove portion is 80% to 120% of the first distance from the first side portion of the anode to the contact hole.

5. The display apparatus according to claim 3, wherein the anode is laterally symmetrical based on a cross section line between the first side portion and the second side portion of the anode.

6. The display apparatus according to claim 1, wherein the planarization layer includes a first planarization layer on the thin film transistor and a second planarization layer on the first planarization layer,
the contact hole includes a first contact hole in the first planarization layer and a second contact hole in the second planarization layer, and
the groove portion has a substantially same depth as the second contact hole.

7. The display apparatus according to claim 6, further comprising:
a connection portion in the second contact hole;
a first connection electrode and a second connection electrode on the first planarization layer,
wherein the second contact hole exposes at least a portion of the first connection electrode, and the connection portion connects the first connection electrode to the anode, and
the groove portion overlaps the second connection electrode and exposes at least a portion of the second connection electrode.

8. The display apparatus according to claim 6, further comprising:
a dummy electrode disposed in the groove portion,
wherein the dummy electrode is provided on a same layer as the anode.

9. The display apparatus according to claim 8, wherein the dummy electrode is spaced apart from the anode.

10. The display apparatus according to claim 8, further comprising:
a first connection electrode and a second connection electrode on the first planarization layer,
wherein the anode is in contact with the first connection electrode through the second contact hole, and
the dummy electrode is in contact with the second connection electrode through the groove portion.

11. A display apparatus, comprising:
a substrate including a plurality of sub-pixels;
a thin film transistor on the substrate;
a planarization layer on the thin film transistor;
an anode on the planarization layer;
a bank on the anode and having an emission area exposing a portion of the anode;
an emission layer disposed on the anode about the emission area; and
a cathode on the emission layer,
wherein the planarization layer includes a first hole adjacent to a first side portion of the emission area and a second hole adjacent to a second side portion of the emission area, the second side portion opposite to the first side portion of the emission area.

12. The display apparatus of claim 11, comprising a connection portion in the first hole, the connection portion connected to the anode,
wherein the anode is separated from the second hole by the bank.

13. The display apparatus of claim 12, comprising a dummy electrode in the second hole, the dummy electrode separated from the anode by a distance.

14. The display apparatus of claim 11, wherein the first hole and the second hole are substantially symmetrical to one another in position with respect to a center line passing through the emission area.

15. The display apparatus of claim 11, wherein a layer of the anode extends into the first hole and the layer of the anode does not extend into the second hole.

16. The display apparatus of claim 11, wherein the first hole has a first width and the second hole has a second width, the second width within a similarity range of the first width.

17. The display apparatus of claim 11, wherein the first hole has a first depth and the second hole has a second depth, the second depth within a similarity range of the first depth.

18. The display apparatus of claim 11, wherein the anode is connected to the thin film transistor through the first hole, and is separated from the second hole by the bank.

19. A display apparatus, comprising:
a substrate;
a thin film transistor on the substrate;
a planarization layer on the thin film transistor;
an anode on the planarization layer;
a bank on the anode and having an opening exposing a first portion of the anode;
wherein the planarization layer includes a first hole and a second hole; and
wherein the first portion of the anode is between the first hole and the second hole.

20. The display apparatus of claim 19, wherein the first hole is substantially symmetrical to the second hole with respect to the first portion of the anode.
